(19) United States
(12) Patent Application Publication
(10) Pub. No.: US 2007/0272297 A1
(43) Pub. Date: Nov. 29, 2007

(54) Disordered silicon nanocomposites for photovoltaics, solar cells and light emitting devices

(76) Inventors: Sergei Krivoshlykov, Shrewsbury, MA (US); Valery Rupasov, Southbridge, MA (US)

Correspondence Address: Dr. Sergei Krivoshlykov, 1 Chartwell Circle, Shrewsbury, MA, 01545, US

(21) Appl. No.: 11/439,626

(22) Filed: May 24, 2006

(51) Int. Cl. H01L 31/00

(52) U.S. Cl. 136/256

(57) ABSTRACT

The present invention describes nanocomposite material structures including layers forming p-n and p-i-n homo- and heterojunctions for application in photovoltaics, solar cells, photodetectors, and light emitting devices, comprising semiconductor nanoparticles, such as colloidal semiconductor nanocrystals, nanorods, nanowires, nanotubes, etc., wherein at least one of the layers is made of hydrogenated amorphous or microcrystalline/nanocrystalline silicon or their alloys enabling low-temperature fabrication processes preventing any degradation of physical properties of the nanoparticles.

### BACKGROUND OF THE INVENTION

1. Field of the Invention

This invention relates to nanocomposite materials and their structures, such as p-n and p-i-n homo- and hetero-junctions, comprising semiconductor nanoparticles, such as colloidal semiconductor nanocrystals, nanorods, nanowires, nanotubes, etc., incorporated into layers made of hydrogenated disordered silicon, including amorphous silicon, microcrystalline (nanocrystalline) silicon or their alloys. Incorporation of the nanoparticles into disordered silicon layers provides good electrical contact between them and disordered silicon matrix, while low-temperature deposition processes of the disordered silicon layers enables to avoid high-temperature degradation of nanoparticle properties. Preferred embodiments include nanocomposite materials with n-type and p-type doped nanoparticles, nanoparticle photovoltaic materials, solar cells, light emitting devices and photodetectors capable to operate in an extremely wide spectral range—from ultraviolet to far-infrared.

2. Background of the Invention

Homojunctions and heterojunctions of both p-n type and p-i-n type made of intrinsic (i), p-type and n-type semiconductor materials have numerous applications in various devices, including photovoltaics, solar cells, photodetectors, and light emitting devices, both light emitting diodes and laser diodes.

For solar cells one of the most important parameters is the efficiency of conversion of solar light energy into electrical energy [M. A. Green, Third Generation Photovoltaics (Bridge Printery, Sydney, 2001)]. The maximum thermodynamic efficiency for the conversion of unconcentrated solar light energy into electrical energy assuming a single threshold absorber was calculated by Shockley and Queisser in 1961 to be about 31% [W. Shockley, H. J. Queisser, J. Appl. Phys. 32, 510 (1961)]. Several schemes for exceeding the Shockley-Queisser limit have been proposed and are under active investigation. These approaches include tandem cells [M. A. Green, Solar Cells, (Prentice-Hall, Englewood Cliffs, N.J., 1982)], “hot” carrier solar cells [D. S. Boudreaux, F. Williams, A. J. Nozik, J. Appl. Phys. 51, 2158 (1980); R. T. Ross, A. J. Nozik, J. Appl. Phys. 53, 3813, (1982); A. J. Nozik, Annu. Rev. Phys. Chem. 52, 193, (2001)], solar cells producing multiple electron-hole pairs per photon through impact ionization (carrier multiplication) [D. S. Boudreaux, F. Williams, and A. J. Nozik, J. Appl. Phys. 51, 2158 (1980); S. Kolodinski et al, Appl. Phys. Lett. 63, 2405 (1993)], multiband and impurity solar cells, as well as thermophotovoltaic/thermophotonic cells [M. A. Green, Third Generation Photovoltaics (Bridge Printery, Sydney, 2001].

Carrier multiplication (CM), which was first observed in bulk semiconductors in the 1950s, would provide increased power conversion efficiency in the form of increased solar cell photocurrent [P. T. Landsberg, H. Nussbaumer, and G. Willeke, J. Appl. Phys. 74, 1451 (1993)]. While CM is very inefficient in bulk semiconductors (the measured CM-induced increase in the efficiencies of traditional solar cells is less than 1%), nanosize semiconductor crystals [nanocrystals (NCs)], might provide a regime where CM could be greatly enhanced through impact ionization [A. J. Nozik, Quantum dot solar cells, Physica (Amsterdam) E 14, 115 (2002); A. J. Nozik, Advanced concepts for photovoltaic cells, NCPV and Solar Program Review Meeting 2003, NREL/CD-520-33586, p. 422.]. This is an Auger-type process whereby a highenergy exciton, created in a semiconductor nanocrystal by absorbing a photon of energy ≧2 E_{g}*, where E_{g}* is the nanocrystal bandgap, relaxes to the band edge via energy transfer of at least 1 E_{g} to a valence band electron, which is excited above the energy gap. The result of this process is that two excitons (electron-hole pairs) are created by one absorbed photon. Thus, this process converts more of the high photon energy portion of the solar spectrum into usable energy.

Ultra-efficient carrier multiplication by one absorbed photon in lead selenide (PbSe) nanocrystals was recently demonstrated by Schaller and Klimov [R. D. Shaller and V. I. Klimov, Phys. Rev. Lett. 92, 186601 (2004)]. They reported a quantum yield (QY) value of 218% at the photon energy equal to 3.8 E_{g}*. QYs above 200% indicate the formation, on average, of more than two excitons per absorbed photon. These results have been confirmed by Ellingson et al. [R. Ellingson el al., Nano Lett. 5, 865 (2005)] for PbSe and lead sulfide (PbS) NCs, and by Shaller et al. [R. D. Shaller, V. M. Agranovich, and V. I. Klimov, Nature Physics 1, 189 (2005)] for cadmium selenide (CdSe) and PbSe NCs. By extending the photon energies up to 8 E_{g}*, QY up to ˜700% in PbSe nanocrystals was recently observed [R. D. Shaller et al., Nano Lett. 6, 424 (2006)], i.e. approximately 7 excitons were produced by one photon.

Thus, semiconductor nanocrystals are extremely efficient generators of many electron-hole pairs per one photon. That could result in development of extremely efficient NC solar cells. However, the characteristic time of Auger recombination of the multiexcitons in NCs is measured to be of the order of 200-300 ps [R. D. Shaller, V. M. Agranovich, and V. I. Klimov, Nature Physics 1, 189 (2005)]. Therefore, for practical implementations of NC solar cells taking advantage of the CM effect one needs to solve the problem of fast and high-efficiency ejection of photogenerated electrons and holes from the nanocrystals.

It is well known that semiconductor nanocrystals are also very attractive light emitters that combine size-controlled emission colors and high-emission efficiencies with excellent photostability and chemical flexibility. Applications of nanocrystals in light emitting devices (light emitting diodes and laser diodes), however, have been significantly hindered by difficulties in achieving direct electrical injection of charge carriers into nanocrystals. The most common approach to electrical “communication” with NCs, including ejection of charges from NCs and their injection into NCs, involves the use of hybrid polymer/NC structures [V. L. Colvin, M. C Schlamp, and A. P. Alivisatos, Nature 370, 354 (1994), B. O. Dabbousi et al., Appl. Phys. Lett. 66, 1316 (1995), N. Tessler et al., Science 295, 1506 (2002), L. Bakueva et al., Appl. Phys. Lett. 82, 2895 (2003), S. Coe et al., Nature 420, 800 (2002)] However, low carrier mobilities in the organic components lead to low device efficiencies.

The other approaches avoiding the use of organic components with low carrier mobilities rely on a purely inorganic architecture to achieve an efficient electrical communication with NCs. All-inorganic architecture of NC photovoltaics and light emitting devices can be viewed, for example, as a p-i-n structure, in which the NCs form the intrinsic (i) layer that is assembled onto a p-type/n-type semiconductor layer and overgrown with an n-type/p-type semiconductor layer. In one of the proposed designs of NC photovoltaics [A. J. Nozik, Advanced concepts for photovoltaic cells, NCPV and Solar Program Review Meeting 2003, NREL/CD-520-33586, p. 422], NCs form an ordered 3-D array between p- and n-layers of a bulk material with sufficiently small inter-NC spacing, such that strong electronic coupling between NCs occurs and NC minibands are formed to allow for long-range electronic transport through NC array. All-inorganic NC devices are obviously stable under ambient atmospheric conditions, but the methods employed for semiconductor thin film growth typically rely on conditions not compatible with NCs.

Nevertheless, the all-inorganic charge injection structure, in which the NCs form the intrinsic layer that is assembled onto a p-type gallium nitride (GaN) layer and overgrown with n-type GaN layer, has been recently realized [A. H. Mueller et al., Nano Lett. 5, 1039 (2005)]. The authors have utilized a new technology, energetic neutral atom beam lithography/epitaxy, that allows for the deposition of high quality semiconducting nitride films at sufficiently low temperatures (<500° C.), thereby avoiding any degradation of the NC that would be associated with high-temperature growth techniques.

Another object for implementations in the invented nanocomposites and their structures is nanotubes, and, in particular, carbon nanotubes (CNTs). During recent years there was enormous academic and industrial research activity on application of carbon nanotubes [R. H. Baughman, A. A. Zakhidov, and W. A. de Heer, Science 297, 787-792 (2002)]. The carbon nanotubes may be either single-walled (SWNT) or multi-walled (MWNT) [R. Saito, G. Dresselhaus, and M. S. Dresselhaus, Physical Properties of Carbon Nanotube (Imperial College Press, London, 1998)]. A single-walled carbon nanotube is a graphite sheet rolled into cylinder, while multi-walled carbon nanotube forms several concentric layers. The diameter of a nanotube can range from 0.7 nm to tens of nanometers, while its length can range up to 100 microns. SWNT exhibit semiconductor or metal conductivity depending of their chirality, i.e. twist of the nanotubes hexagonal lattice-structured wall [C. Dekker, Physics Today 52, 22 (1999)]. The nanotubes can be ether grown in the form of ordered or disordered arrays (nanotube forest) or in the form of nanotube powder.

Employing ordered arrays of single-walled carbon nanotubes for development of infrared detectors and their potential advantages over semiconductor photodetectors based on quantum wells and quantum dots were recently discussed in the literature [J. M. Xu, Infrared Physics and Technology 42, 485-491 (2001)]. The possibility of incorporation of the carbon nanotubes into semiconductor matrices opens door to simple and cost-efficient fabrication of photovoltaic materials and light emitting devices operating in a wide IR spectral range. While nanotubes made of wide-gap semiconductor materials, such as boron nitride (BN) and silicon carbide (SiC), can be employed for development of light emitting devices operating in ultraviolet and visible spectral ranges.

In the present invention, semiconductor nanoparticles-colloidal semiconductor nanocrystals, nanorods, nanowires, nanotubes, etc.—are proposed to be incorporated into i-type, p-type or n-type layers made of either hydrogenated amorphous silicon (a-Si:H) [R. A. Street, Hydrogenated amorphous silicon, (Cambridge University Press, 1991)] or hydrogenated microcrystalline silicon (μc-Si:H) and their alloys, including hydrogenated amorphous silicon-germanium (a-Si₁₋ₓGeₓ:H) and hydrogenated amorphous silicon-carbon (a-Si₁₋ₓCₓ:H) alloys. In other possible design, nanoparticles can form an intrinsic layer sandwiched between n- and p-layers, at least one of which is made of disordered silicon to avoid high-temperature degradation of nanoparticle properties.

Microcrystalline silicon (μc-Si) is similar to amorphous silicon, in that it has an amorphous phase. Where they differ, however, is that μc-Si has small grains of crystalline silicon within the amorphous phase. This is in contrast to polycrystalline silicon (poly-Si), which consists solely of crystalline silicon grains separated by grain boundaries. Microcrystalline silicon is sometimes also known as nanocrocrystalline silicon (nc-Si). The difference comes solely from size of the crystalline grains. Microcrystalline silicon has many useful advantages over a-Si, one being that if grown properly it can have a higher charge mobility, due to the presence of the silicon crystallites. One of the most important advantages of μc-Si, however, is that it has increased stability over a-Si, one of the reasons being because of its lower hydrogen concentration. Although it currently cannot attain the charge mobility that poly-Si can, it has the advantage over poly-Si that it is easier to fabricate, as it can be deposited using conventional low-temperature a-Si deposition techniques, such as plasma enhanced chemical vapor deposition (PECVD) method.

Thus, the proposed technology, employing low-temperature (75-250° C.) deposition processes, such as PECVD, allows encapsulation of nanoparticles into both intrinsic and doped semiconductor matrices without any high-temperature degradation of nanoparticle properties. This solves thus the problem of direct electrical communication between a semiconductor matrix and nanoparticles. Moreover, the energy structure, including size and position of the energy bandgap of amorphous and microcrystalline silicon alloys, can be adjusted in a wide energy range—from approximately 1.2 eV to over 3 eV—by changing the composition of the alloys. That allows optimization of the photovoltaic materials and adjustment of the operating frequency of light emitting devices in an extremely wide spectral range—from ultraviolet to far-infrared.

### OBJECTS AND SUMMARY OF THE INVENTION

It is an object of the present invention to provide intrinsic, p-type, or n-type nanocomposite layers made of disordered-amorphous or microcrystalline/nanocrystalline-silicon or their alloys and comprising semiconductor nanoparticles encapsulated into disordered silicon matrix that ensures a direct electrical contact between the disordered silicon matrix and nanoparticles.

Another object is to provide a method of efficient doping semiconductor nanoparticles by incorporating them into p- or n-doped matrix made of disordered silicon material.

Another object is to provide nanocomposite disordered silicon materials comprising n-type or p-type doped semiconductor nanoparticles.

Another object of the invention is to provide nanocomposite disordered silicon materials and their structures for photovoltaics.

Still another object of the invention is to provide nanocomposite disordered silicon materials and their structures for large area, flexible photovoltaics.

A further object is to provide nanocomposite disordered silicon materials and their structures for high-efficiency solar cells taking advantage of the carrier multiplication effect in colloidal semiconductor nanocrystals.

Another object of the invention is to provide nanocomposite disordered silicon materials and their structures for light emitting devices, including both light emitting diodes and laser diodes.

Another object is to provide nanocomposite disordered silicon materials and their structures for large area, flexible light emitting diodes.

Still another object of the invention is to provide nanocomposite disordered silicon materials and their structures for large area, flexible, single- and multi-collar light emitting diodes.

Another object is to provide nanocomposite disordered silicon structures for photovoltaic materials, including structures with carbon nanotubes, nanowires and nanorods.

A further object of the invention is to provide nanocomposite disordered silicon structures for light emitting devices, including structures with carbon nanotubes, nanowires and nanorods.

Briefly stated, the present invention describes nanocomposite materials and their p-n and p-i-n homo- and hetero-junctions for photovoltaic materials, solar cells, photodetectors, and light emitting devices, comprising semiconductor nanoparticles, such as colloidal semiconductor nanocrystals, nanorods, nanowires, nanotubes, etc., wherein at least one of the layers is made of hydrogenated amorphous or microcrystalline/nanocrystalline silicon or their alloys enabling low-temperature deposition processes preserving physical properties of the nanoparticles.

Although, describing preferred embodiments of the present invention, we refer, for the sake of illustration, to colloidal spherical semiconductor nanocrystals and carbon nanotubes, the preferred embodiments are obviously not limited to these particular cases, but include also other semiconductor crystals of nanoscale size, such as, e.g., nanorods and nanowires, as well as nanotubes made of other materials, such as, e.g., boron nitride (BN) and silicon carbide (SiC).

### BRIEF DESCRIPTION OF DRAWINGS

The above, and other objects, features and advantages of the present invention will become apparent from the following description read in conjunction with the accompanying drawings:

FIG. 1 illustrates the energy level structure of a spherical semiconductor nanocrystal;

FIG. 2 illustrates position of the energy level structure of a spherical semiconductor nanocrystals relative to vacuum level;

FIG. 3 illustrates the density of electronic states of disordered silicon;

FIG. 4 shows the NC-disordered silicon energy bandgap alignment required for doping nanocrystals with electrons;

FIG. 5 shows the NC-disordered silicon energy bandgap alignment required for doping nanocrystals with holes;

FIG. 6 shows an energy diagram of nanocomposite p-n homo junction.

FIG. 7 illustrates the nanocrystal-disordered silicon energy bandgap alignment desired for photovoltaic materials;

FIG. 8 shows the nanocrystal-disordered silicon energy bandgap alignment desired for light emitting devices;

FIG. 9 illustrates a disordered silicon nanostructured p-i-n junction, where nanocrystals form the intrinsic layer sandwiched between the n- and p-type layers;

FIG. 10 shows one possible energy bandgap alignment in a heterostructures comprising hydrogenated disordered silicon and a bulk semiconductor material;

FIG. 11 shows another possible energy bandgap alignment in a heterostructures comprising hydrogenated disordered silicon and a bulk semiconductor material;

FIG. 12 illustrates one of possible designs of a CNT photovoltaic material;

FIG. 13 illustrates the desired energy bandgap alignment of CNTs and electron- and hole-collecting layers in CNT photovoltaic materials.

Further scope of applicability of the present invention will become apparent from the detailed description given hereafter. However, it should be understood that the detailed descriptions and specific examples, while including the preferred embodiments of the invention, are given by way of illustration only, since various changes and modifications within the spirit and scope of the invention will become apparent to those skilled in the art from this detailed description.

### DESCRIPTION OF PREFERRED EMBODIMENTS

The preferred embodiments are directed to nanocomposite materials and their structures for photovoltaics, photodetectors, and light emitting devices. A key element of the preferred embodiments is a p-type, i-type or n-type layer made of disordered-amorphous or microcrystalline-silicon and comprising semiconductor nanoparticles encapsulated into the disordered silicon host. The intrinsic, p-type or n-type layers of the disordered silicon comprising nanocrystals can obviously be employed in numerous layered architectures already proposed for photovoltaic materials and light emitting devices. Apart from the nanocomposite disordered silicon layers, these structures can also comprise bulk semiconductor materials, metals, and conducting polymers. That enables development of numerous layered architectures taking advantage of nanoparticles as efficient photogenerators of electron-hole pairs for photovoltaic applications and as very attractive light emitters combining size-controlled emission colors and high-emission efficiencies with excellent photostability and chemical flexibility for light emitting device applications.

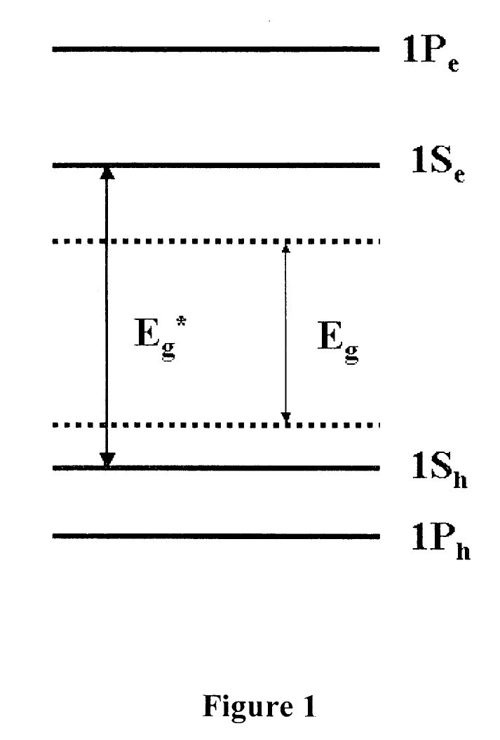

FIG. 1 illustrates the energy level structure of a spherical semiconductor nanocrystal in the simplest model “particle-in-box” [Al. L. Efros and M. Rosen, Annu. Rev. Mat. Sci. 2000. 30: 475-521]. The figure shows only two lowest spatially quantized levels in the conduction band and two highest spatially quantized energy levels in the valence band. Doted lines show the edges of the conduction and valence bands of a semiconductor material the nanocrystal is made of, and E_{g} is the energy gap in the bulk semiconductor material. E_{g}* is the energy gap in the nanocrystal, i.e. the difference between energies of the lowest and highest levels in the conduction and valence bands, respectively. We also use conventional spectroscopic notation for the levels, where letters S and P correspond to the angular momentum of electrons and holes l=0 and 1, respectively. In the ground state, all the energy levels in the valence band are occupied with two electrons having different spins, while all the energy levels in the conduction band are unoccupied. In most preferred embodiments, the energy gap of nanocrystal is much bigger than the thermal energy at room temperature, E_{g}*>>k_{B} T, where k_{B} is the Boltzmann constant. Therefore, one can neglect population of the conduction band and the depletion of the valence band, which are inessential at room temperature.

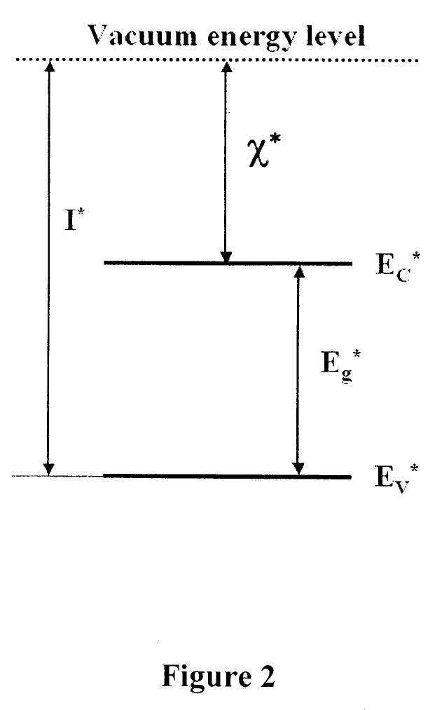

FIG. 2 illustrates the definitions of electron affinity (χ*) and ionization potential (I*) for semiconductor nanocrystals. The electron affinity is defined as the energy of the lowest energy level in the conduction band with respect to the vacuum energy, while the ionization potential is defined as the energy of the highest level in the valence band with respect to the vacuum energy, i.e. I*=χ*+E_{g}*. It is also convenient to use notations for the edges of the conduction and valence bands of a nanocrystal with respect to vacuum level—E_{C}* for the energy of the lowest energy level in the conduction band, E_{C}*=χ*, and E_{V}* for the highest energy level in the valence band, E_{V}*=1*, and E_{V}*−E_{C}*=E_{g}*.

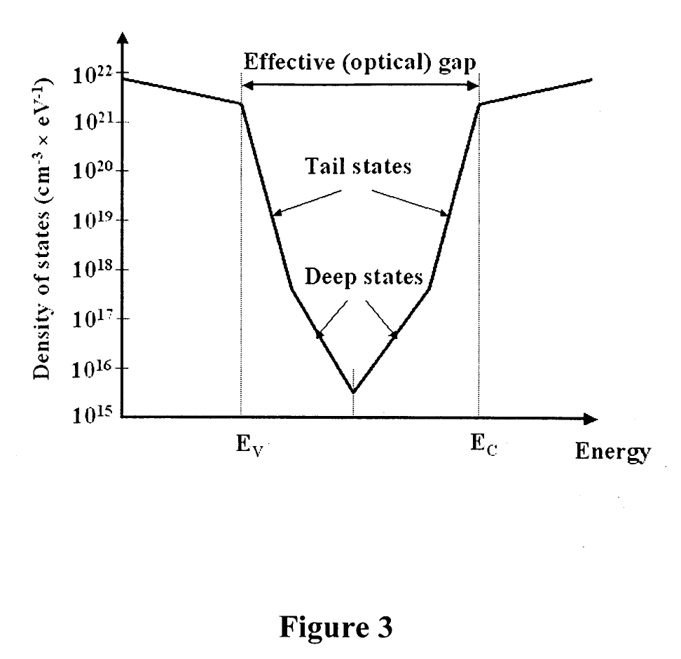

FIG. 3 illustrates the density of electronic states of disordered-amorphous and microcrystalline-silicon. The materials currently used in a-Si:H based solar cells are deposited, e.g., by the plasma enhanced chemical vapor deposition (PECVD) process. These materials are in fact silicon hydrogen alloys that typically contain about 5 to 20 at. % of hydrogen. The intrinsic disorder of the material creates broken bonds, which negatively impact the electronic properties of disordered silicon materials. Passivation of the broken bonds by hydrogen reduces their electrical density from ˜10¹⁹ cm⁻³ present in unhydrogenated a-Si to as low as 10¹⁵ cm⁻³ in a-Si:H. The incorporation of hydrogen and disorder also has a profound effect on the bandgap and optical absorption. Disordered silicon does not behave like an indirect bandgap semiconductor so that even though its bandgap increases to ˜1.8 eV it has very high optical absorption typically associated with direct bandgap semiconductors. Because of the low densities of defects in intrinsic materials incorporation of dopants during deposition allows formation of both n-type and p-type materials making the disordered silicon unique amongst disordered (amorphous) materials.

Since basic crystal structure in disordered silicon is absent, there is no well-defined bandgap, but a range of energies with a few states. The effective (optical) gap ranges in the interval 1.5-1.8 eV [H. Sato el al., Solar Energy Materials & Solar Cells 66, 321 (2001)], depending on fabrication process. Another property, which greatly enhances the flexibility of a-Si based materials, is the ability to fabricate various alloys, in particular amorphous silicon-germanium (a-Si₁₋ₓGeₓ:H) and amorphous silicon-carbon (a-Si₁₋ₓ:Cₓ:H) alloys. The optical bandgaps of these alloys can be adjusted depending of their composition. They can be made as low as 1.2 eV for the a-silicon-germanium and as high as 3.3 eV for a-silicon-carbon materials [D. Dimova-Malinoska et al., Solar Energy Materials & Solar Cells 53, 333 (1998); G. Ambrosone et al., Philos. Mag. B 82, 35 (2002)].

Although in disordered silicon there is no well-defined energy gap, one can neglect the density of electron states inside the effective gap, which is insignificant for our applications, and treat the charge mobility edges E_{C} and E_{V} as the bottom and top of the conduction and the valence bands, respectively. As in the case of nanocrystals, it is convenient to measure the energies E_{C} and E_{V} from the vacuum energy level.

From measurements of the internal photoemission at a c-Si/a-Si:H heterojunction, where c-Si stands for the crystalline one, Mimura and Hatanaka [H. Mimura and Y. Hatanaka, Appl. Phys. Lett. 50, 326 (1986)] concluded that the major band edge discontinuity occurs in the valence band (0.71 eV), while it is only 0.09 eV in the conduction band. The energy gap was measured to be E_{g}=1.92 eV, although the optical band gap was ˜1.8 eV. Since in amorphous silicon the band edges are not clearly determined, these values are acceptable for estimates. Thus, the band edges of a-Si according to Miura and Hatanaka measurements can be estimated to be E_{C}=3.9 eV and E_{V}=5.8 eV, and the energy gap E_{g}=1.9 eV. It should be emphasized that the energy parameters of disordered silicon depend on the deposition process and are strongly affected by alloying with, for example, germanium and carbon, and by grain size in μc-Si. Therefore, the energy parameters are given for illustration only, while real designs of the preferred embodiments may require more careful measurements and estimates.

Some measurements [G. E. N. Landweer and P. Roca i Cabarrocas, Appl. Surface Science 109/110, 579 (1996)] show that the work function (i.e. the Fermi energy with respect to the vacuum energy level) of intrinsic a-Si:H has a value around 4.5 eV, while n-type/p-type doping may decrease/increase the work function by the value of 0.5 eV.

The disordered silicon technology enables developing of an efficient method for n-type and p-type doping of the semiconductor nanoparticles by embedding them into n-type or p-type disordered silicon layers or by other means of establishing a sufficiently good electrical contact with these layers.

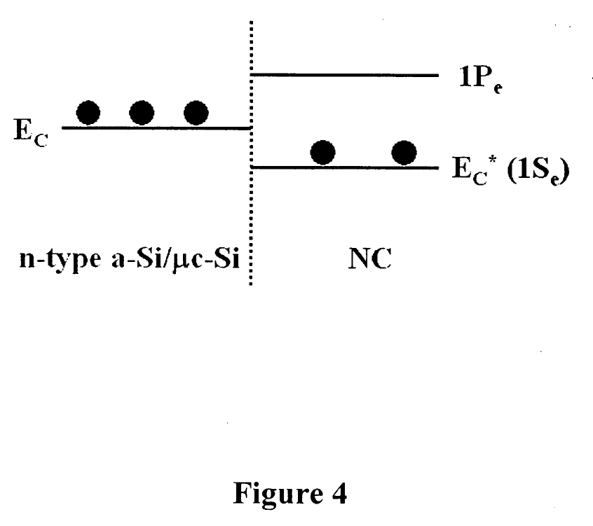

FIG. 4 shows the conduction band alignment of n-type disordered silicon and NCs required for doping NCs with electrons. At the alignment shown in FIG. 4, electrons from the conduction band of the n-type disordered silicon layer are injected into nanocrystals and occupy only the lowest energy level (1Sₑ) in the NC conduction band, while the higher energy levels remain unoccupied. Controlling the level of doping of disordered silicon, i.e. the density of electrons in the conduction band, and the density of nanocrystals in the layer, one can control average population of level 1Sₑ of the NC system. Moreover, the density of nanocrystals and the density of electrons in the conduction band of disordered silicon layer can be obviously chosen such that almost all electrons will be localized in the nanocrystals occupying the energy level 1Sₑ, provided that the energy difference between the conduction band edges of disordered silicon and NCs, ΔE=E_{C}−E_{C}*, essentially exceeds temperature T, ΔE>>k_{B} T, where k_{B} is the Boltzmann constant, and one can neglect inessential temperature population of disordered silicon states.

At the energy bandgap alignment, when other spatially quantized energy levels of NCs, e.g. 1Pₑ, 1Dₑ etc., also lie below the edge of the conduction band of disordered silicon layer, E_{C}, they can be also doped with electrons at sufficiently high density of electrons in the conduction band.

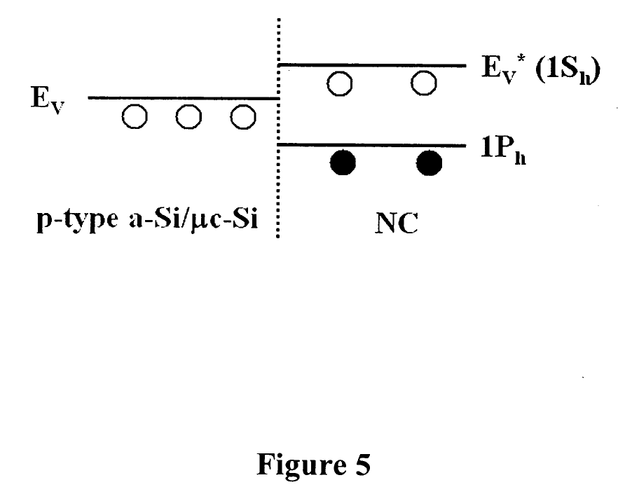

FIG. 5 shows the valence band alignment of p-type disordered silicon and NCs required for doping NCs with holes. At the alignment shown in FIG. 5, holes from valence band of disordered silicon are injected into nanocrystals and occupy the highest energy level (1Sₕ) in the NC valence band. While the lower energy levels are occupied with electrons. Again, controlling the level of doping of disordered silicon, i.e. the density of holes in the valence band, and the density of nanocrystals in the layers, one can control average population of the level 1Sₕ of the NC system, as well as other spatially quantized energy levels in the valence band of NCs lying above the edge of the valence band of p-doped disordered silicon layer.

The described method of doping the colloidal semiconductor nanocrystals can be obviously generalized to the cases of other nanoparticles, such as nanorods, nanowires and nanotubes.

The invented method allows one to engineer various nanocomposite optical materials employing intraband optical transitions in the semiconductor nanoparticles.

One of the preferred embodiments of the invented method of doping also includes doping of recently developed MWNT sheets [M. Zhang el al, Strong, Transparent, Multifunctional, Carbon Nanotube Sheets, Science 309, 1215 (2005)] enabling to significantly increase their conductivity for numerous applications.

Nanocomposite disordered silicon layers also enable development of numerous homo- and hetero-structures analogous to the structures made of bulk materials. For the sake of illustration only, we describe below the simplest nanocomposite layered structures for photovoltaic and light emitting device applications.

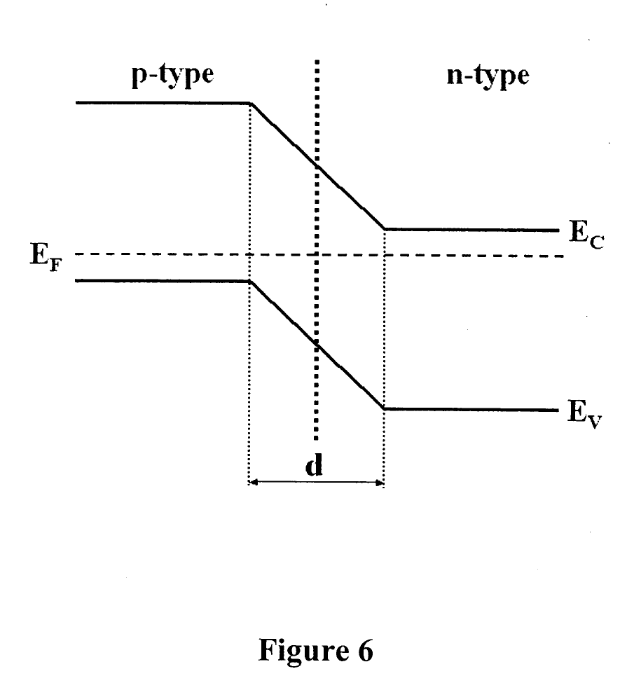

FIG. 6 shows a typical energy structure of a simplest p-n homojunction made of p-type and n-type layers of disordered silicon. Here, nanocrystals are incorporated into the depletion zone of the width d formed in the junction, which is shown by bold dot line. As it occurs in currently used a-Si based solar cells, the width of the depletion zone can be increased in p-i-n homojunction, where an intrinsic layer is sandwiched between p-type and n-type layers. In the p-i-n junction NCs can be incorporated into a sufficiently wide intrinsic layer to enhance the device performance. In another possible design recently realized by Klimov et al. [R. D. Shaller et al., Nano Lett. 5, 1039 (2005)], one or several monolayers of nanocrystals form the intrinsic layer sandwiched between p-type and n-type layers.

The described nanocomposite p-n and p-i-n homojunctions can be used for both photovoltaic materials and light emitting devices. But various applications obviously require different energy bandgap alignments between the disordered silicon and nanocrystals.

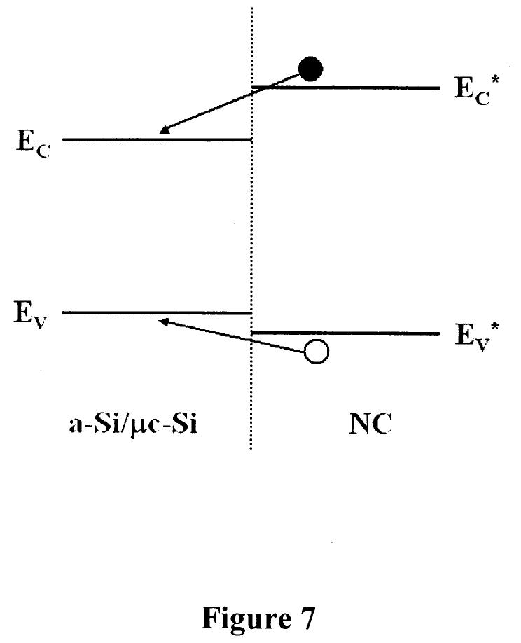

FIG. 7 illustrates the energy bandgap alignment required for photovoltaic materials. Such a straddled alignment, where the energy gap of disordered silicon lies inside the energy gap of nanocrystals, provides efficient ejection of electrons and holes photogenerated into NCs assisted by strong built-in electrical field in the depletion layer of p-n or p-i-n junction.

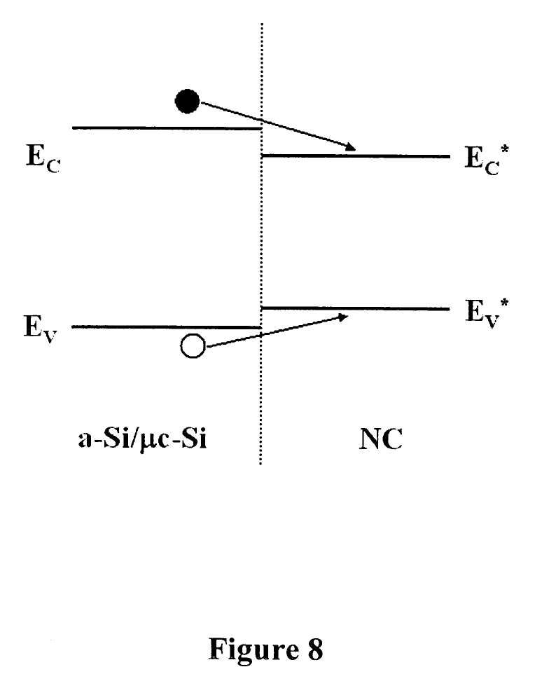

FIG. 8 shows the energy bandgap alignment required for light emitting devices. Such a straddled alignment, where the energy gap of nanocrystals lies inside the energy gap of disordered silicon, provides efficient injection of electrons and holes from n-type and p-type layers respectively under an appropriate electrical voltage applied to p-n or p-i-n junction.

The nanocomposite disordered silicon layers obviously allow development of various nanocrystal p-n and p-i-n heterojunctions for numerous applications in photovoltaic, light emitting and other semiconductor devices. Apart from the nanocomposite disordered silicon layers, these structures can also comprise bulk semiconductor materials, metals, and conducting polymers. That enables to realize various layered architectures known from the literature and currently used in numerous applications employing analogous architectures comprising the proposed nanocomposite disordered silicon layers.

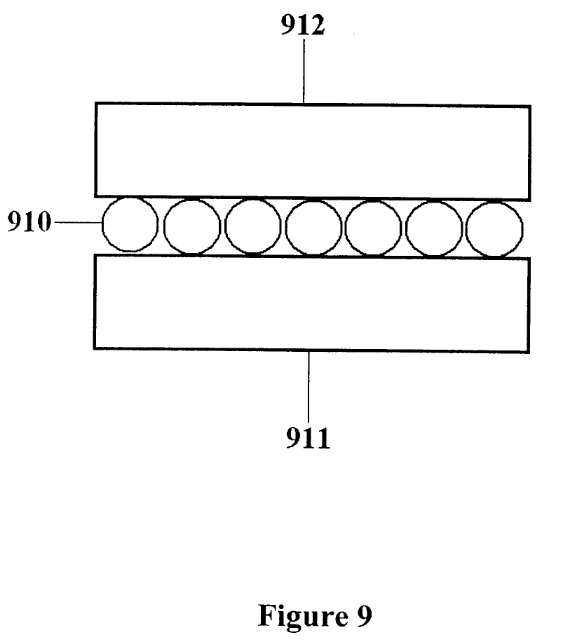

FIG. 9 illustrates a disordered silicon p-i-n junction, where nanocrystals form the intrinsic layer sandwiched between n- and p-type layers. Here, a dense Langmuir-Blodgett nanocrystal monolayer 910 forms the intrinsic layer that is assembled onto layer 911 and overgrown with layer 912. To avoid high temperature degradation of NCs, the layer 912 overgrowing over the NC layer is made of disordered silicon or its alloys, while the layer 911 can be made of disordered silicon too or, e.g., of a bulk semiconductor material. It is obvious also that the intrinsic NC layer can comprise more than one monolayer.

At an appropriate energy bandgap alignment between nanocrystals, disordered silicon alloy layer, and a bulk semiconductor material the third layer is made of, the nanostructured p-i-n junctions can be used for both photovoltaic and light emitting devise applications. Moreover, an appropriate choice of materials of the heterostructure and material and size of the nanocrystals enables to realize devices with required parameters.

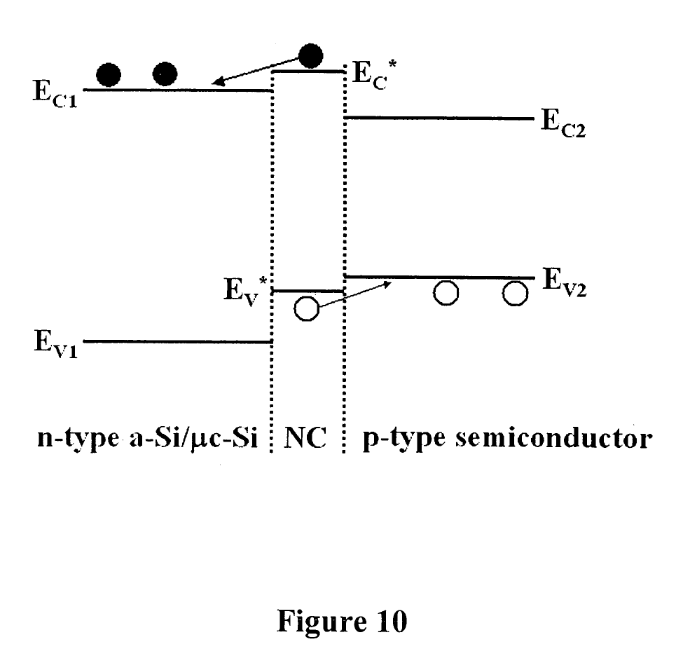

FIG. 10 shows one of possible bandgap alignments in a heterostructure comprising n-type hydrogenated disordered silicon and p-type bulk semiconductor, whereby the energy bandgap of the bulk, E_{g2}, is smaller than the energy bandgap of disordered silicon, E_{g1}, E_{g2}<E_{g1}. The edges of the conduction and valence bands measured with respect to the vacuum energy level are E_{C1}, E_{V1} for disordered silicon and E_{C2}, E_{V2} for the bulk. Nanocrystals are sandwiched between n- and p-type layers.

If the edges of the conduction and valence bands of nanocrystals, E_{C}* and E_{V}*, are positioned as shown in FIG. 8 and the NC bandgap E_{g}* exceeds the effective bandgap of the heterostructure E_{g}=E_{V2}−E_{C1}, then electrons and holes photogenerated in the nanocrystals are ejected from NCs by built-in electrical field into n-type and p-type layers respectively, as illustrated in FIG. 8. Such heterostructures can be used to optimize the power conversion efficiency of photovoltaic materials. For example, if the bulk semiconductor material in the heterostructure is germanium with E_{C2}=4.0 eV and E_{V2}=4.66 eV, the effective bandgap of the heterostructure, E_{g}=E_{V2}−E_{C1}, is as small as 0.76 eV. That is very close to the optimum bandgap of 0.8 eV [P. T. Landsberg, H. Nussbaumer, and G. Willeke, J. Appl. Phys. 74, 1451 (1993)], which is required to take advantage of the carrier multiplication effect in NCs and achieve the maximum thermodynamic efficiency of solar cell exceeding 60%.

If the energy bandgap of NCs is smaller than the effective energy bandgap of the heterostructure, E_{g}*<E_{g}, electrons and holes are injected into NCs under an appropriate external electrical voltage applied the heterostructure. Therefore, such heterostructures can be used to optimize an electrical pump of light emitting devices operating in the near-IR spectral range. For light emitting devices operating in the visible and UV spectral ranges, one can use the heterostructures with a wide band gap bulk semiconductor material.

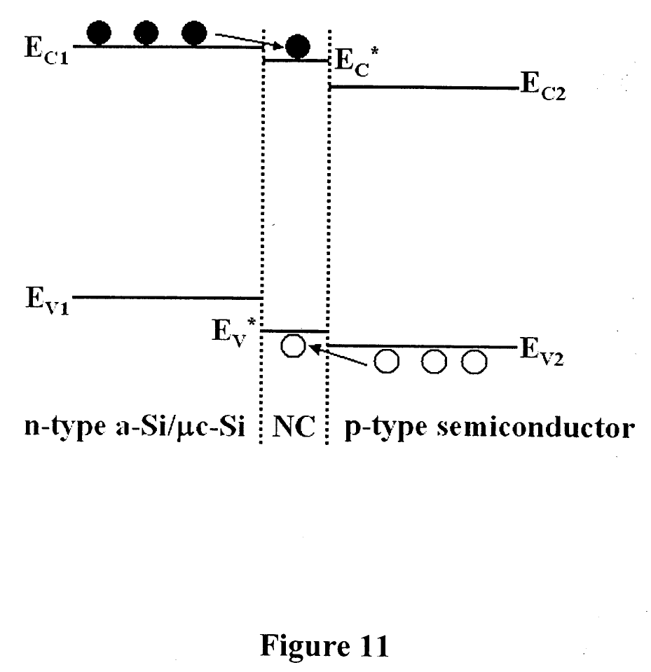

FIG. 11 illustrates bandgap alignment of the NC heterostructure comprising n-type hydrogenated disordered silicon and p-type bulk semiconductor, whereby the energy bandgap of the bulk, E_{g2}, exceeds the energy bandgap of disordered silicon layer, E_{g2}>E_{g1}. For example, if the bulk semiconductor material in the heterostructure is gallium nitride (GaN) with E_{C2}=4.1 eV and E_{V2}=7.3 eV (for zinc blende crystal structure) or E_{V2}=7.5 eV (for wurtzite crystal structure), the effective energy gap of the heterostructure, E_{g}=E_{V2}−E_{C1}, is as large as 3.4 eV or 3.6 eV. That enables to electrically pump NCs with the energy gap just slightly less than 3.4 or 3.6 eV, and thus to develop light emitting devices operating in ultraviolet spectral range.

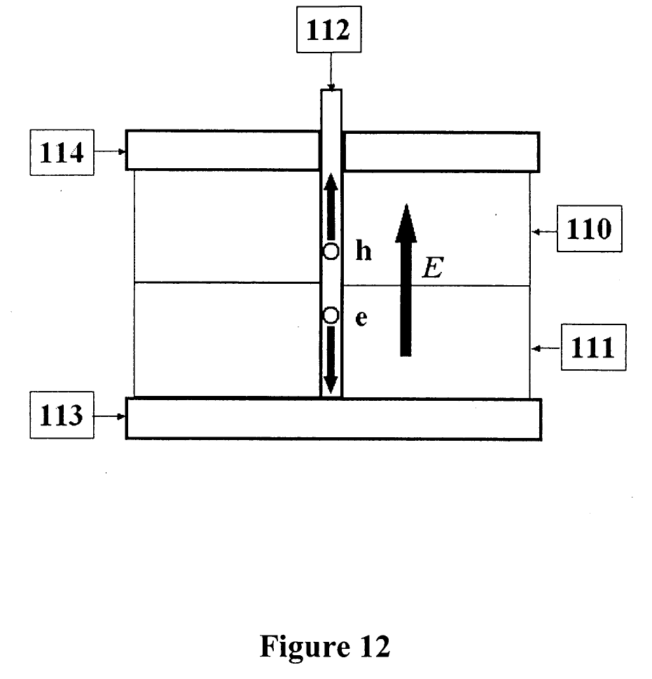

FIG. 12 illustrates one of possible designs of carbon nanotube (CNT) photovoltaic material sensitive to IR light that can be employed for IR-imaging devices. In the proposed design, an array of single- or multi-walled carbon nanotubes incorporated into p-n junction made of disordered silicon layers works as a photovoltaic material. The level of doping and thicknesses of the doped layers are assumed to be chosen such that all free charge carriers are mutually recombine, and in the ground state the photovoltaic material does not contain any free charge carriers.

The built-in electric field E of the p-n junction made of p-type (210) and n-type (211) disordered silicon layers spatially separates electrons and holes photogenerated by IR radiation inside a CNT (212). In amorphous silicon, the magnitudes of the bottom of the conduction band, E_{C}, and the top of the valence band, E_{V}, with respect to the vacuum energy level, were measured to be approximately E_{C}=3.9 eV and E_{V}=5.8 eV. Since, the work function of CNTs, W_{NT}, is estimated to be in the range of 4.5-4.8 eV, the energies of both electrons and holes photogenerated inside CNTs by IR photons lie well inside the energy gap of a-Si. Therefore, both electrons and holes are well confined inside CNTs. Photogenerated charges propagate inside nanotubes only and are collected by the electron- (213) and hole-collecting (214) electrodes. The collected charges can be then measured by making use of the same technique like employed in conventional silicon-based charge coupled devices (CCDs) operating in the near-IR spectral range.

In the p-n junction, width of the depletion layer is determined by the level of doping and varies from approximately 0.1 to 1 micron. To essentially increase the “working” length of CNTs, an intrinsic disordered silicon layer can be deposited between p- and n-type layers, so that the working length. L_{W}, in the developed p-i-n junction, will be determined by the total length of the depletion layers, d, and the width of the i-layer, Dᵢ, L_{W}=Dᵢ+d.

Although the intrinsic layer decreases the strength of the built-in electric field, extremely high mobility, μ, of charge carriers in CNTs, which is estimated to be approximately 10⁵-10⁶ cm²/Vsec, provides very fast spatial separation of photogenerated charges. For example, at the working length L_{W}=10 μm, and the built-in field strength E=10³ V/cm, corresponding to the potential difference of 1 V, the drift velocity of charge carriers is found to be V_{drift}=μ E=10⁸-10⁹ cm/sec. Therefore, the time required for separation of charges from the working length of nanotubes, τₛ=L_{W}/v_{drift}, is estimated to be 1-10 ps. That time is at least two-three orders of magnitude shorter than the characteristic time of photo-recombination of charge carriers in CNTs.

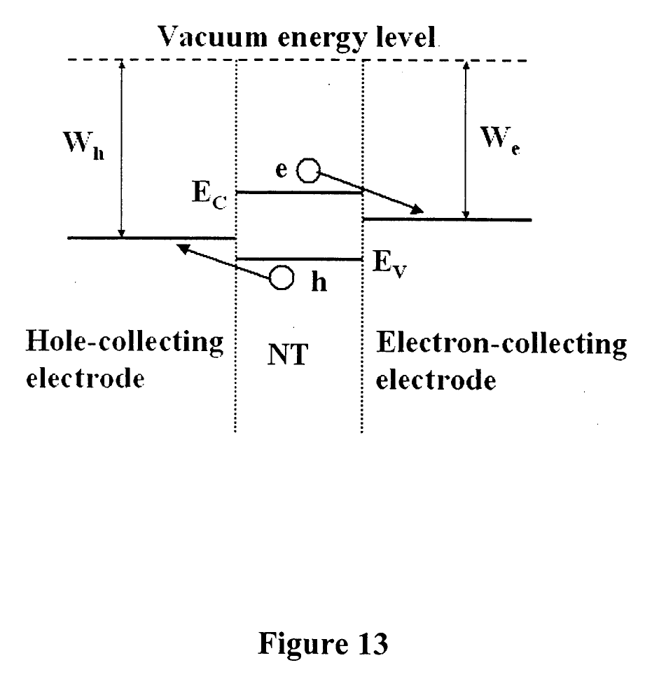

FIG. 13 shows the preferred energy band alignment between CNTs and electron-collecting and hole-collecting electrodes. Here, Wₑ and Wₕ stand for work functions of the electron-collecting and hole-collecting electrodes, respectively. To effectively collect all photogenerated electrons, the work function of the electron-collecting electrode should be larger than the electron energy in CNTs, Wₑ>E_{C}. This electrode can be made, e.g., of such metals as nickel (Ni) with work function W_{Ni}=5.01 eV, gold (Au) with W_{Au}=5 eV, or platinum (Pt) with W_{Pt}=6.35 eV, that ensures effective electron collection. The CNT arrays can be grown on the substrate made of these metals.

From the other side, to effectively collect photogenerated holes, the work function of the hole-collecting electrode, Wₕ, should be less than the energy of holes in CNTs, Wₕ<E_{V}. Moreover, the hole-collecting electrode must be well transparent in spectral range of device operation (or the electrode must be sufficiently thin) and admit low-temperature deposition preventing high-temperature degradation of CNTs. For example, the electrode can be made of widely used indium-tin-oxide having the work function ranging in the interval of 4.5-4.7 eV.

At an appropriate selection of materials of electrodes operating now as electron-transfer and hole-transfer layers with work functions Wₑ>E_{C} and Wₕ<E_{V} required for an effective injection of charge carriers into CNTs, the proposed CNT device can obviously operate also as a light emitting device. In this light emitting device the electrons and holes, injected into CNTs under an appropriate external voltage applied to the electrodes, recombine inside nanotubes with emission of IR photons. Moreover, the proposed design can also be implemented employing wide-gap nanotubes made of such semiconductor materials as BN and SiC, as well as employing semiconductor nanorods and nanowires. That obviously enables fabrication of the nanocomposite light emitting diodes and laser diodes operating in ultraviolet and visible spectral ranges.

Having described preferred embodiments of the invention with reference to the accompanying drawings, it is to be understood that the invention is not limited to the precise embodiments, and that various changes and modifications may be effected therein by skilled in the art without departing from the scope or spirit of the invention as defined in the appended claims.

What is claimed is:

1. An intrinsic, p-type or n-type nanocomposite disordered silicon layer, wherein foreign semiconductor nanoparticles, such as colloidal semiconductor nanocrystals, nanorods, nanowires, nanotubes, are incorporated into an intrinsic, p-type or n-type disordered silicon layer, respectively, made of hydrogenated amorphous silicon, hydrogenated microcrystalline silicon or their alloys, including hydrogenated silicon-germanium and hydrogenated silicon-carbon alloys, which are fabricated by a low-temperature processes preserving physical properties of said nanoparticles.

2. An n-type nanocomposite disordered silicon layer of claim 1, wherein the energy bandgap alignment between said nanoparticles and said n-type disordered silicon layer is chosen such to ensure doping said nanoparticles with at least one election from the conduction band of said n-type disordered silicon layer.

3. A p-type nanocomposite disordered silicon layer of claim 1, wherein the energy bandgap alignment between said nanoparticles and said p-type disordered silicon layer is chosen such to ensure doping said nanoparticles with at least one hole from the valence band of said p-type disordered silicon layer.

4. A nanocomposite disordered silicon structure, comprising at least one intrinsic, p-type or n-type disordered silicon layer of claim 1.

5. A nanocomposite disordered silicon structure of claim 4 comprising at least one p-type or n-type nanocomposite disordered silicon layer forming p-n junction either between themselves or with another disordered silicon layer or with a bulk semiconductor material for application in photovoltaics, solar cells and light emitting devices.

6. A nanocomposite disordered silicon structure of claim 5 forming p-n junction for application in photovoltaics and solar cells, wherein the energy bandgap alignment between said nanoparticles and said p-n junction is chosen such to ensure ejection of both electrons and holes, photogenerated into said nanoparticles, followed by spatial separation of the ejected electrons and holes to n-type and p-type layer-s of said p-n junction, respectively.

7. A nanocomposite disordered silicon structure of claim 6 forming p-n junction for application in solar cells, wherein said nanoparticles are semiconductor nanocrystals, the energy bandgap of said nanocrystals and the energy bandgap alignment between said nanocrystals and said p-n junction are additionally chosen such to take advantage of the carrier multiplication effect in the nanocrystals increasing the power conversion efficiency of said solar cell.

8. A nanocomposite disordered silicon structure of claim 5 forming p-n junction for application in light emitting devices, wherein the energy bandgap alignment between said nanoparticles and said p-n junction is chosen such to ensure injection of both electrons and holes from n-type and p-type layers of said p-n junction, respectively, into said nanoparticles under an appropriate external electrical voltage, applied to said p-n junction, followed by photo-recombination of the electrons and holes injected into said nanoparticles.

9. A nanocomposite disordered silicon structure of claim 4 comprising at least one p-type, i-type or n-type nanocomposite disordered silicon layer forming p-i-n junction either between themselves or with other disordered silicon layers or with a bulk semiconductor material for application in photovoltaics, solar cells and light emitting devices.

10. A nanocomposite disordered silicon structure of claim 9 forming p-i-n junction for application in photovoltaics and solar cells, wherein the energy bandgap alignment between said nanoparticles and said p-i-n junction is chosen such to ensue ejection of both electrons and holes, photogenerated into said nanoparticles, followed by spatial separation of ejected electrons and holes to n-type and p-type layers of said p-i-n junction, respectively.

11. A nanocomposite disordered silicon structure of claim 10 forming p-i-n junction for application in solar cells, wherein said nanoparticles are semiconductor nanocrystals, the energy bandgap of said nanocrystals and the energy bandgap alignment between said nanocrystals and said p-i-n junction are additionally chosen such to take advantage of the carrier multiplication effect in the nanocrystals for increasing the power conversion efficiency of said solar cells.

12. A nanocomposite disordered silicon structure of claim 9 forming p-i-n junction for application in light emitting devices, wherein the energy bandgap alignment between said nanoparticles and said p-n junction is chosen such to ensure injection of both electrons and holes from n-type and p-type layers of said p-n junction, respectively, into said nanoparticles under an appropriate external electrical voltage, applied to said p-n junction, followed by photo-recombination of the electrons and holes injected into said nanoparticles.

13. A nanocomposite disordered silicon structure of claim 4 forming p-i-n junction for application in photovoltaics, solar cells and light emitting devices, wherein semiconductor nanoparticles form the intrinsic layer sandwiched between the p-type and n-type layers, at least one of which is p-type or n-type disordered silicon layer.

14. A nanocomposite disordered silicon structure of claim 13 forming p-i-n junction for application in photovoltaics and solar cells, wherein the energy bandgap alignment between said nanoparticles and said p-n junction is chosen such to ensure election of both electrons and holes, photogenerated into said nanoparticles, followed by spatial separation of ejected electrons and holes to n-type and p-type layers of said p-n junction, respectively.

15. A nanocomposite disordered silicon structure of claim 14 forming p-i-n junction for application in solar cells, wherein said nanoparticles are semiconductor nanocrystals, the energy bandgap of said nanocrystals and the energy bandgap alignment between said nanocrystals and said p-i-n junction are additionally chosen such to take advantage of the carrier multiplication effect in the nanocrystals increasing the power conversion efficiency of said solar cells.

16. A nanocomposite disordered silicon structure of claim 13 forming p-i-n junction for application in light emitting devices, wherein the energy bandgap alignment between said nanoparticles and said p-n junction ensures efficient injection of both electrons and holes from n-type and p-type layers, respectively, into nanoparticles under an external electrical voltage applied to said p-i-n junction followed by photo-recombination of the electrons and holes injected into said nanoparticles.

17. A nanocomposite disordered silicon structure for application in photovoltaics comprising:
at least one p-n junction made of p-type and n-type disordered silicon layers made of hydrogenated amorphous silicon, hydrogenated microcrystalline silicon or their alloys, including hydrogenated silicon-germanium and hydrogenated silicon-carbon alloys, and
at least one foreign nanoparticle, including single-walled or multi-walled nanotubes, nanorods, nanowires, incorporated into said p-n junction,
wherein electrons and holes photogenerated in said nanoparticles are spatially separated inside said nanoparticles by built-in electric field of said p-n junction.

18. A nanocomposite disordered silicon structure of claim 17 for application in photovoltaics, comprising additional electron-collecting and hole-collecting electrodes which are in electrical contact to said nanoparticles, and are made of materials ensuring ejection of electrons and holes from said nanoparticles into said electron-collecting and hole-collecting electrodes, respectively.

19. A nanocomposite disordered silicon structure of claim 17 for application in photovoltaics, wherein said nanoparticles are nanotubes, including single-walled or multi-walled carbon nanotubes, boron nitride nanotubes, silicon carbide nanotubes.

20. A nanocomposite disordered silicon structure of claim 17 for application in photovoltaics comprising an additional intrinsic disordered silicon layer sandwiched between the p-type and n-type layers of said p-n junction.
